(19) United States
(12) Patent Application Publication
(10) Pub. No.: US 2026/0198115 A1
(43) Pub. Date: Jul. 9, 2026

(54) LIGHT RECEIVING ELEMENT, IMAGING ELEMENT, AND IMAGING DEVICE

(71) Applicant: SONY SEMICONDUCTOR SOLUTIONS CORPORATION, Kanagawa (JP)

(72) Inventor: Shunsuke MARUYAMA, Kanagawa (JP)

(73) Assignee: SONY SEMICONDUCTOR SOLUTIONS CORPORATION, Kanagawa (JP)

(21) Appl. No.: 19/127,630

(22) PCT Filed: Nov. 25, 2022
(86) PCT No.: PCT/JP2022/043468

§ 371 Date: May 6, 2025

(51) Int. Cl. H10F 39/00

(52) U.S. Cl. CPC H10F 39/805; H10F 39/806

(57) ABSTRACT

A light receiving element, an imaging element, and an imaging device that can prevent reflection of incident light over a wide wavelength range from visible light to infrared light are provided. A photoelectric conversion layer containing a compound semiconductor material or an organic material, a semiconductor layer arranged on a light incident surface side than the photoelectric conversion layer, containing a compound semiconductor material that prevents recombination of charges generated by photoelectric conversion by the photoelectric conversion layer, and having a film thickness thinner than the photoelectric conversion layer, a first insulating layer arranged on the light incident surface side than the semiconductor layer, containing silicon nitride, and having a lower refractive index than the semiconductor layer, and a second insulating layer arranged on the light incident surface side than the first insulating layer, containing silicon oxide, and having a lower refractive index than the first insulating layer are included.

### TECHNICAL FIELD

The present disclosure relates to a light receiving element, an imaging element, and an imaging device.

### BACKGROUND ART

An imaging device has been proposed that includes a light receiving element that can receive light in a wavelength band from visible light to infrared light using InGaAs in a photoelectric conversion layer (refer to Patent Document 1). The light receiving element disclosed in Patent Document 1 has a laminated structure including a surface recombination preventing layer that includes a first compound semiconductor and in which light enters, a photoelectric conversion layer including a second compound semiconductor, and a compound semiconductor layer including a third compound semiconductor. This surface recombination preventing layer has a thickness equal to or less than 30 nm. By thinning the surface recombination preventing layer, it is possible to prevent absorption of visible light by this layer and to provide the light receiving element that has high sensitivity with respect to the wavelength band form the visible light to the infrared light.

A transparent conductive material layer is formed on a light incident surface of the surface recombination preventing layer. An antireflection film including SiO₂ is formed, on a light incident surface of the transparent conductive material layer.

### CITATION LIST

### Patent Document

Patent Document 1: Japanese Patent Application Laid-Open No. 2018-125538

### SUMMARY OF THE INVENTION

### Problems to be Solved by the Invention

Since the antireflection layer of the light receiving element disclosed in Patent Document 1 includes only one layer including SiO₂, reflection can be prevented in a part of the wavelength band from the visible light to the infrared light. However, there is a possibility that incident light in other wavelength bands is reflected. Therefore, it is difficult to prevent the reflection of the incident light over a wide wavelength band range from the visible light to the infrared light.

Therefore, the present disclosure provides a light receiving element, an imaging element, and an imaging device that can prevent reflection of incident light over a wide wavelength band range from visible light to infrared light.

### Solutions to Problems

In order to solve the above problems, according to the present disclosure, a light receiving element is provided that includes
a photoelectric conversion layer containing a compound semiconductor material or an organic material,
a semiconductor layer arranged on a light incident surface side than the photoelectric conversion layer, containing a compound semiconductor material that prevents recombination of charges generated by photoelectric conversion by the photoelectric conversion layer, and having a film thickness thinner than the photoelectric conversion layer,
a first insulating layer arranged on the light incident surface side than the semiconductor layer, containing silicon nitride, and having a lower refractive index than the semiconductor layer, and
a second insulating layer arranged on the light incident surface side than the first insulating layer, containing silicon oxide, and having a lower refractive index than the first insulating layer.

A plurality of layers including the semiconductor layer, the first insulating layer, and the second insulating layer arranged on the light incident surface side from the photoelectric conversion layer may have a smaller refractive index, as approaching the light incident surface.

An antireflection layer may be included that is arranged on a light incident surface side than the semiconductor layer and has a two-layer structure in which the first insulating layer including a silicon nitride layer and the second insulating layer including a silicon oxide layer are laminated.

The semiconductor layer may have a film thickness equal to or more than 10 nm and equal to or less than 30 nm.

A transparent electrode layer may be further included that is arranged between the semiconductor layer and the first insulating layer.

A third insulating layer may be further included that is arranged between the transparent electrode layer and the first insulating layer, contains silicon oxide, and has a film thickness equal to or less than 10 nm.

A fourth insulating layer may be further included that is arranged between the semiconductor layer and the first insulating layer, contains silicon oxide, and has a film thickness equal to or less than 10 nm.

A fifth insulating layer may be further included that is arranged between the first insulating layer and the second insulating layer, contains at least one of aluminum oxide, magnesium oxide, or titanium oxide, and has a film thickness equal to or less than 10 nm.

A sixth insulating layer may be further included that is arranged on the light incident surface side than the second insulating layer, contains at least one of silicon nitride, aluminum oxide, magnesium oxide, or titanium oxide, and has a film thickness equal to or less than 10 nm.

The first insulating layer may have a film thickness equal to or more than 20 nm and equal to or less than 180 nm.

The second insulating layer may have a film thickness equal to or more than 20 nm and equal to or less than 180 nm.

The photoelectric conversion layer may contain InGaAs.

The photoelectric conversion layer may have a layer structure in which a first layer containing InGaAs and a second layer containing GaAsSb are alternately laminated.

The photoelectric conversion layer may have a distorted InGaAs structure containing InₓGa₍₁₋ₓ₎As (x is equal to or more than 0.53).

The photoelectric conversion layer may contain the organic material of which a refractive index is equal to or more than three.

The semiconductor layer may contain InP, InGaAs, or InAlAs.

An imaging element is provided that includes
a light receiving element, and
a filter that is arranged on a light incident surface side than the light receiving element and transmits light in a predetermined wavelength band, in which
the light receiving element includes
a photoelectric conversion layer that contains a compound semiconductor material or an organic material,
a semiconductor layer that is arranged on the light incident surface side than the photoelectric conversion layer, contains a compound semiconductor material, and has a film thickness thinner than the photoelectric conversion layer,
a first insulating layer that is arranged on the light incident surface side than the semiconductor layer, contains silicon nitride, and has a lower refractive index than the semiconductor layer, and
a second insulating layer that is arranged on the light incident surface side than the first insulating layer, contains silicon oxide, and has a lower refractive index than the first insulating layer.

An imaging device in which a plurality of imaging elements each including a light receiving element, and
a filter that is arranged on a light incident surface side of the light receiving element and transmits light in a predetermined wavelength band is arranged in a one-dimensional or two-dimensional direction, in which
the light receiving element includes
a photoelectric conversion layer that contains a compound semiconductor material or an organic material,
a semiconductor layer that is arranged on the light incident surface side than the photoelectric conversion layer, contains a compound semiconductor material, and has a film thickness thinner than the photoelectric conversion layer,
a first insulating layer that is arranged on the light incident surface side than the semiconductor layer, contains silicon nitride, and has a lower refractive index than the semiconductor layer, and
a second insulating layer that is arranged on the light incident surface side than the first insulating layer, contains silicon oxide, and has a lower refractive index than the first insulating layer.

### BRIEF DESCRIPTION OF DRAWINGS

FIG. 1 is a block diagram depicting an embodiment of a solid-state imaging device to which the present technology is applied.

FIG. 2 is a circuit diagram depicting a schematic configuration example of a unit pixel.

FIG. 3 is a cross-sectional view depicting a cross-sectional structure example of a pixel according to a first embodiment.

FIG. 4 is a graph depicting a calculation result of a wavelength and a reflection ratio of incident light entering a light receiving element that includes an antireflection layer of a first film thickness condition.

FIG. 5 is a graph depicting a calculation result of a wavelength and a reflection ratio of incident light entering a light receiving element that includes an antireflection layer of a second film thickness condition.

FIG. 6 is a graph depicting a calculation result of a wavelength and a reflection ratio of incident light entering a light receiving element that includes an antireflection layer of a third film thickness condition.

FIG. 7 is a graph depicting a calculation result of a wavelength and a reflection ratio of incident light entering a light receiving element that includes an antireflection layer of a fourth film thickness condition.

FIG. 8 is a graph depicting a calculation result of a wavelength and a reflection ratio of incident light entering a light receiving element that includes an antireflection layer of a fifth film thickness condition.

FIG. 9 is a graph depicting a calculation result of a wavelength and a reflection ratio of incident light entering a light receiving element that includes an antireflection layer of a sixth film thickness condition.

FIG. 10 is a graph depicting a calculation result of a wavelength and a reflection ratio of incident light entering a light receiving element that includes an antireflection layer of a seventh film thickness condition.

FIG. 11 is a graph depicting a calculation result of a wavelength and a reflection ratio of incident light entering a light receiving element that includes an antireflection layer of an eighth film thickness condition.

FIG. 12 is a graph depicting a relationship between a film thickness of an insulating layer and an evaluation result of an antireflection performance.

FIG. 13 is a cross-sectional view depicting a cross-sectional structure of a pixel according to a second embodiment.

FIG. 14 is a cross-sectional view depicting a cross-sectional structure of a pixel according to a third embodiment.

FIG. 15 is a cross-sectional view depicting a cross-sectional structure of a pixel according to a fourth embodiment.

FIG. 16 is a cross-sectional view depicting a cross-sectional structure of a pixel according to a fifth embodiment.

FIG. 17 is a cross-sectional view depicting a cross-sectional structure of a pixel according to a sixth embodiment.

FIG. 18 is a cross-sectional view depicting a cross-sectional structure of a pixel according to a seventh embodiment.

FIG. 19 is a block diagram depicting an example of a schematic configuration of a vehicle control system.

FIG. 20 is an explanatory diagram depicting an example of installation positions of an outside-vehicle information detecting section and an imaging section.

### MODE FOR CARRYING OUT THE INVENTION

Hereinafter, embodiments of a light receiving element, an imaging element, and an imaging device will be described with reference to the drawings. Although principal components of the light receiving element, the imaging element, and the imaging device will be mainly described below, components and functions that are not depicted or described may exist in the light receiving element, the imaging element, and the imaging device. The following description is not intended to exclude components and functions that are not depicted or described.

### FIRST EMBODIMENT

### Schematic Configuration Example of Solid-State Imaging Device

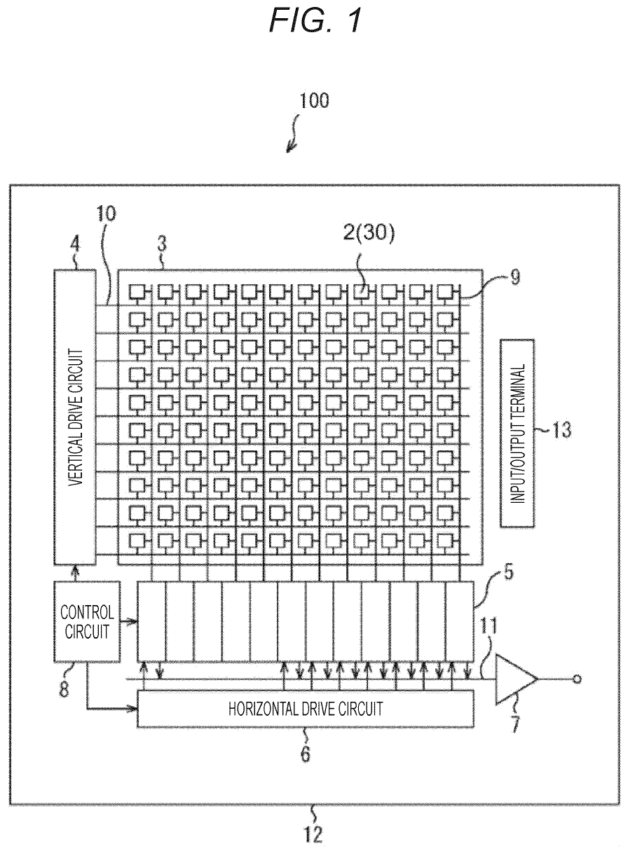

FIG. 1 is a block diagram depicting an embodiment of a solid-state imaging device to which the present technology is applied. A solid-state imaging device 100 according to a first embodiment includes an imaging element and a light receiving element 30 to which the present technology is applied. The solid-state imaging device 100 can configure a part of an electronic apparatus.

The solid-state imaging device 100 includes, for example, a pixel array region 3 in which pixels 2 are two-dimensionally arranged in a matrix and a peripheral circuit region therearound, on a semiconductor substrate 12 using monocrystalline silicon (Si). The peripheral circuit region includes a vertical drive circuit 4, a column signal processing circuit 5, a horizontal drive circuit 6, an output circuit 7, a control circuit 8, or the like.

The light receiving element 30 is provided for each pixel 2. The pixel 2 includes a photoelectric conversion section including a semiconductor thin film and a plurality of pixel transistors. The plurality of pixel transistors includes, for example, three MOS transistors including a reset transistor, an amplification transistor, and a selection transistor.

The control circuit 8 receives an input clock and data giving a command of an operation mode and the like and outputs data of internal information of the solid-state imaging device 100 and the like. That is, the control circuit 8 generates a clock signal and a control signal which serve as a reference for an operation of the vertical drive circuit 4, the column signal processing circuit 5, the horizontal drive circuit 6, and the like on the basis of a vertical synchronization signal, a horizontal synchronization signal, and a master clock. Then, the control circuit 8 outputs the generated clock signal and control signal to the vertical drive circuit 4, the column signal processing circuit 5, the horizontal drive circuit 6, and the like.

The vertical drive circuit 4 includes, for example, a shift register (not depicted), selects a predetermined pixel drive wiring line 10 and supplies a pulse for driving the pixel 2 to the selected pixel drive wiring line 10 to drive the pixels 2 in row units. That is, the vertical drive circuit 4 sequentially selects and scans the pixels 2 of the pixel array region 3 in row units in a longitudinal direction and supplies a pixel signal based on a signal charge generated according to a received light amount by the photoelectric conversion section of each of the pixels 2, to the column signal processing circuit 5 through a vertical signal line 9.

The column signal processing circuit 5 is arranged, for each column of the pixels 2 and executes signal processing such as analog-digital conversion (hereinafter, AD conversion) and noise removal on the signal output from the pixels 2 in one row for each column. The noise removal includes correlated double sampling (CDS) processing to remove pixel-specific fixed pattern noise. The column signal processing circuit 5 outputs AD-converted pixel data from which noise has been removed.

The horizontal drive circuit 6 includes, for example, a shift register, sequentially selects the column signal processing circuits 5 by sequentially outputting horizontal scanning pulses, and causes each of the column signal processing circuits 5 to output the pixel data to a horizontal signal line 11.

The output circuit 7 executes signal processing on the pixel data sequentially supplied from each column signal processing circuits 5 through the horizontal signal line 11, and outputs a processed signal. There is a case where the output circuit 7 merely buffers, for example, or a case where the output circuit 7 performs black level adjustment, column variation correction, various types of digital signal processing, or the like. An input/output terminal 13 exchanges signals with outside.

The solid-state imaging device 100 in FIG. 1 is a CMOS image sensor called a column AD system in which the column signal processing circuit 5 that executes the CDS processing and the AD conversion processing is arranged for each column. Note that the solid-state imaging device 100 according to the present embodiment may adopt a pixel AD system that performs AD conversion for each pixel 2.

### Pixel Circuit

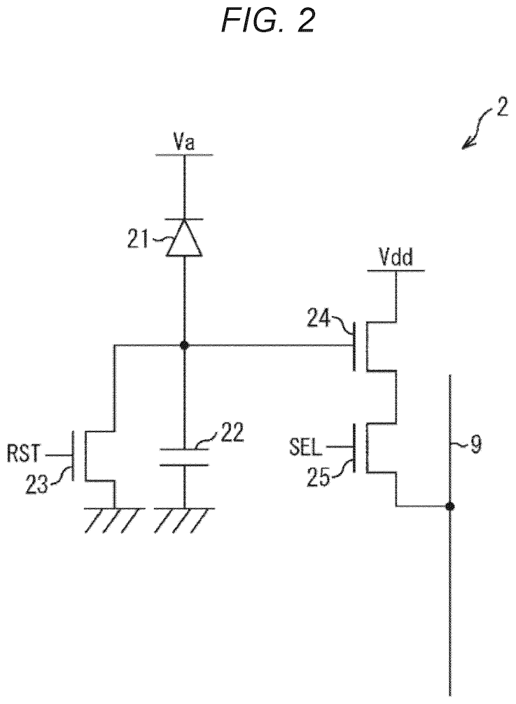

FIG. 2 is a circuit diagram depicting a schematic configuration example of a unit pixel. Each pixel 2 includes a photoelectric conversion section 21, a capacitor element 22, a reset transistor 23, an amplification transistor 24, and a selection transistor 25.

The photoelectric conversion section 21 includes a semiconductor thin film using a compound semiconductor such as InGaAs and generates a charge (signal charge) according to an amount of received light. A predetermined bias voltage Va is applied to the photoelectric conversion section 21.

The capacitor element 22 accumulates the charge generated by the photoelectric conversion section 21. The capacitor element 22 may include, for example, at least one of a PN junction capacitance, a MOS capacitance, or a wiring capacitance.

When turned on by a reset signal RST, the reset transistor 23 resets a potential of the capacitor element 22, by discharging the charges accumulated in the capacitor element 22 to a source (ground).

The amplification transistor 24 outputs a pixel signal according to an accumulated potential of the capacitor element 22. That is, the amplification transistor 24 constitutes a load MOS (not depicted) as a constant current source connected via the vertical signal line 9 and a source follower circuit. As a result, a pixel signal indicating a level according to the charge accumulated in the capacitor element 22 is output from the amplification transistor 24 to the column signal processing circuit 5 via the selection transistor 25.

The selection transistor 25 is turned on when the pixel 2 is selected by a selection signal SEL, and outputs the pixel signal of the pixel 2 to the column signal processing circuit 5 via the vertical signal line 9. Each signal line through which the selection signal SEL and the reset signal RST are transmitted corresponds to the pixel drive wiring line 10 in FIG. 1.

### Cross-Sectional Structure of Pixel

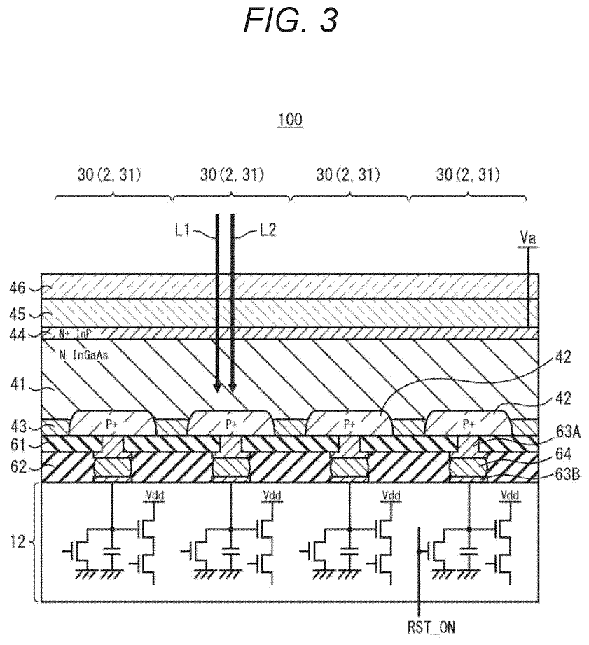

Next, a pixel structure of an imaging element 31 according to the first embodiment will be described. FIG. 3 is a cross-sectional view depicting a cross-sectional structure example of the pixel 2 according to the first embodiment.

In the solid-state imaging device 100, the plurality of light receiving elements 30 is arranged in a one-dimensional or two-dimensional direction. As described above, the light receiving element 30 is provided for each pixel 2. The light receiving element 30 according to the present embodiment includes a photoelectric conversion layer 41, a semiconductor layer 44 arranged on a light incident surface side than the photoelectric conversion layer 41, a first insulating layer 45 arranged on the light incident surface side than the semiconductor layer 44, and a second insulating layer 46 arranged on the light incident surface side than the first insulating layer 45.

The imaging element 31 includes the light receiving element 30.

A reading circuit of the capacitor element 22, the reset transistor 23, the amplification transistor 24, and the selection transistor 25 of each pixel 2 described with reference to FIG. 2 is formed for each pixel, on the semiconductor substrate 12 including a monocrystalline material, for example, monocrystalline silicon (Si) or the like. Note that, in the cross-sectional view in FIG. 3 and subsequent drawings, illustration of reference numerals of the capacitor element 22, the reset transistor 23, the amplification transistor 24, and the selection transistor 25 formed on the semiconductor substrate 12 is omitted.

On an upper side that is a light incident side of the semiconductor substrate 12, the N-type photoelectric conversion layer 41 to be the photoelectric conversion section 21 is formed on an entire region of the pixel array region 3. The N-type photoelectric conversion layer 41 includes a compound semiconductor such as InGaP, InAlP, InGaAs, InAlAs, or a chalcopyrite structure. The compound semiconductor having the chalcopyrite structure is a material that obtains a high light absorption coefficient and high sensitivity over a wide wavelength range and is preferably used as the N-type photoelectric conversion layer 41 that performs photoelectric conversion. Such a compound semiconductor having the chalcopyrite structure is configured using elements around group IV elements such as Cu, Al, Ga, In, S, or Se, and a CuGaInS-based mixed crystal, CuAlGaInS-based mixed crystal, a CuAlGaInSSe-based mixed crystal, and the like are exemplified.

Furthermore, the photoelectric conversion layer 41 may include an organic material. The photoelectric conversion layer 41 may contain an organic material of which a refractive index is equal to or more than three. For example, as a material of the photoelectric conversion layer 41, in addition to the compound semiconductors described above, amorphous silicon (Si), germanium (Ge), a quantum dot photoelectric conversion film, an organic photoelectric conversion film, or the like may be used.

In the present embodiment, an example in which a compound semiconductor of InGaAs is used as the N-type photoelectric conversion layer 41 will be mainly described.

On a lower side that is the semiconductor substrate 12 side of the N-type photoelectric conversion layer 41, a high-concentration P-type semiconductor layer 42 included in a pixel electrode is formed for each pixel. Then, between the high-concentration P-type semiconductor layers 42 formed for the respective pixels 2, an N-type semiconductor layer 43 as a pixel separation region for separating each pixel 2 is formed. The semiconductor layer 43 includes, for example, a compound semiconductor such as InP. This N-type semiconductor layer 43 has a role for preventing a dark current, in addition to a function as the pixel separation region.

On the other hand, on an upper side that is a light incident side of the N-type photoelectric conversion layer 41, the N-type semiconductor layer 44 having a higher concentration than the N-type photoelectric conversion layer 41 is formed, using a compound semiconductor such as InP used as the pixel separation region. This high-concentration semiconductor layer 44 functions as a barrier layer that prevents recombination of the charges generated in the N-type photoelectric conversion layer 41. In other words, the semiconductor layer 44 contains a compound semiconductor material that prevents the charges generated by photoelectric conversion in the photoelectric conversion layer 41 from moving in a reverse direction and being recombined.

The semiconductor layer 44 has a thinner film thickness than the photoelectric conversion layer 41. The semiconductor layer 44 has a film thickness equal to or more than 10 nm and equal to or less than 30 nm. The semiconductor layer 44 contains InP, InGaAs, or InAlAs. For example, as a material of the semiconductor layer 44, a compound semiconductor such as InP, InGaAs, or InAlAs can be used.

The light receiving element 30 includes a two-layer structure insulating layers 45 and 46 in which the first insulating layer 45 including a silicon nitride layer and the second insulating layer 46 including a silicon oxide layer are laminated as an antireflection layer. Note that, for these insulating layers 45 and 46, a transparent insulating layer is used to cause visible light L1 and infrared light L2 to pass through. Note that “transparent” here does not mean to transmit incident light with all wavelengths and means to transmit at least a part of incident light having the wavelength band of the visible light or the infrared light.

The first insulating layer 45 is formed on the semiconductor layer 44. The first insulating layer 45 contains silicon nitride and has a film thickness equal to or more than 20 nm and equal to or less than 180 nm. The first insulating layer 45 has a lower refractive index than the semiconductor layer 44 including InP, for example. In this way, a plurality of layers including the semiconductor layer 44, the first insulating layer 45, and the second insulating layer 46 arranged on the light incident surface side from the photoelectric conversion layer 41 may have a smaller refractive index as approaching the light incident surface.

An upper electrode is arranged on an upper side of the photoelectric conversion layer 41, and a lower electrode is arranged on a lower side of the photoelectric conversion layer 41. The upper electrode includes, for example, the semiconductor layer 44. The predetermined bias voltage Va is applied to the upper electrode. The lower electrode includes the high-concentration P-type semiconductor layer 42 configuring the pixel electrode as described later.

The second insulating layer 46 contains silicon oxide and has a film thickness equal to or more than 20 nm and equal to or less than 180 nm. The second insulating layer 46 has a lower refractive index than the first insulating layer 45 including the silicon nitride layer.

According to the above, in the light receiving element 30 according to the present embodiment, the semiconductor layer 44, the first insulating layer 45, and the second insulating layer 46 formed on the photoelectric conversion layer 41 are configured to have a lower refractive index as separating from the photoelectric conversion layer 41. In this way, by laminating the plurality of layers of which the refractive index is lowered in a stepwise manner, from the photoelectric conversion layer 41 to the light incident surface side, the light entered the light incident surface is less likely to be reflected by the plurality of layers, a ratio of the incident light reaching the photoelectric conversion layer 41 can be increased, and a photoelectric conversion efficiency can be improved.

Note that, for the first insulating layer 45 and the second insulating layer 46, silicon nitride (SiN), silicon oxide (SiO₂), hafnium oxide (HfO₂), aluminum oxide (Al₂O₃), zirconium oxide (ZrO₂), tantalum oxide (Ta₂Ta₅), titanium oxide (TiO₂), or the like may be used. However, materials of the first insulating layer 45 and the second insulating layer 46 are selected such that the first insulating layer 45 has a lower refractive index than the semiconductor layer 44 and the second insulating layer 46 has a lower refractive index than the first insulating layer 45.

As a result, a configuration is obtained in which the plurality of imaging elements 31 including the light receiving element 30 is arranged in the one-dimensional or two-dimensional direction, in the solid-state imaging device 100.

With such a configuration, as depicted in FIG. 3, the visible light L1 and the infrared light L2 as the incident light pass through the second insulating layer 46, the first insulating layer 45, and the semiconductor layer 44 and are photoelectrically converted by the photoelectric conversion layer 41.

On a lower side of the high-concentration P-type semiconductor layer 42 included in the pixel electrode and the N-type semiconductor layer 43 as the pixel separation region, a passivation layer 61 and an insulating layer 62 are formed. Then, connection electrodes 63A and 63B and a bump electrode 64 are formed to penetrate the passivation layer 61 and the insulating layer 62. The connection electrodes 63A and 63B and the bump electrode 64 electrically connect the high-concentration P-type semiconductor layer 42 included in the pixel electrode and the capacitor element 22 that accumulates charges.

### Calculation Result

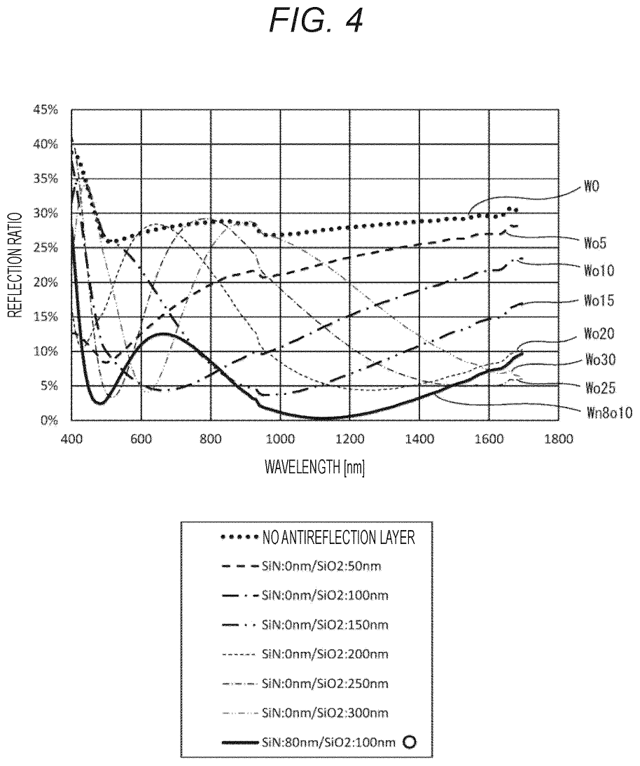

Next, a calculation result of the reflection ratio in a case where the antireflection layer including the first insulating layer 45 and the second insulating layer 46 described above is used will be described with reference to FIGS. 4 to 12. Here, a calculation result of the reflection ratio in a case where the film thickness of the first insulating layer 45 including the silicon nitride layer and the film thickness of the second insulating layer 46 including the silicon oxide layer are changed will be described.

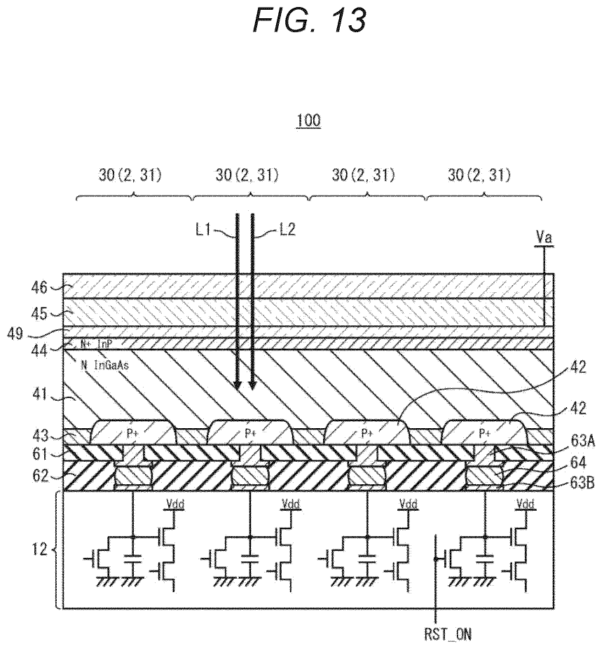

First, a calculation result of a condition in which the film thickness of one of the first insulating layer 45 and the second insulating layer 46 is set to zero nm and the film thickness of the other is changed within a range from zero nm to 300 nm will be described. In this calculation, calculation has been made as assuming a configuration including the semiconductor layer 44 including InP having a film thickness of 30 nm and the photoelectric conversion layer 41 including InGaAs having an infinite film thickness. Furthermore, the calculation has been made as assuming a configuration in which a transparent electrode layer 49 (refer to FIG. 13) having a film thickness of 10 nm is included between the semiconductor layer 44 and the first insulating layer 45.

First, a first film thickness condition will be described in which the film thickness of the first insulating layer 45 including silicon nitride is set to zero nm and the film thickness of the second insulating layer 46 including silicon oxide is changed within a range from zero nm to 300 nm. FIG. 4 is a graph depicting a calculation result of a wavelength and a reflection ratio of incident light entering the light receiving element 30 including the antireflection layer of the first film thickness condition. Note that, in FIG. 4, a waveform Wn8o10 in a case where the film thickness of the first insulating layer 45 including silicon nitride is set to 80 nm and the film thickness of the second insulating layer 46 including silicon oxide is set to 100 nm is also depicted, as a preferable setting example of the film thickness in the present disclosure.

In FIG. 4, seven waveforms W0, Wo5, Wo10, Wo15, Wo20, Wo25, and Wo30 are depicted in which the film thickness of the second insulating layer 46 is changed from zero nm to 300 nm at 50 nm intervals. That is, in FIG. 4, a change in the reflection ratio in a case where the film thickness of the second insulating layer 46 including a single silicon oxide layer is caused to be different is depicted.

In these waveforms, as depicted in FIG. 4, the reflection ratio is rapidly lowered from around a wavelength of 400 nm of the incident light, and the reflection ratio increases in a wavelength band in which the wavelength is 600 nm to 1000 nm to form a first peak. Furthermore, in these waveforms, the reflection ratio is lowered again in a longer wavelength band than this peak, and is increased again to around a wavelength of 1700 nm depicted in FIG. 4. Therefore, under the first film thickness condition, for example, it is difficult to suppress the reflection ratio in a wide wavelength range in a visible light wavelength band in which the wavelength is from about 400 nm to about 800 nm or an infrared light wavelength band in which the wavelength exceeds 800 nm. That is, it is not possible for this antireflection layer to suppress the reflection at a wavelength of 400 nm to 1700 nm, and there is a wavelength band where sensitivity is extremely dropped.

On the other hand, in the waveform Wn8o10, in which the reflection ratio is preferred, indicated by a solid line in FIG. 4, after the reflection ratio is lowered from the wavelength of 400 nm to 500 nm, the reflection ratio falls below 15% up to the wavelength of 1700 nm. In this way, by using the antireflection layer in which the film thicknesses of the first insulating layer 45 and the second insulating layer 46 are appropriately set, as indicated by the waveform Wn8o10, it is possible to suppress the reflection over a wide band and excellently maintain the sensitivity as the light receiving element 30.

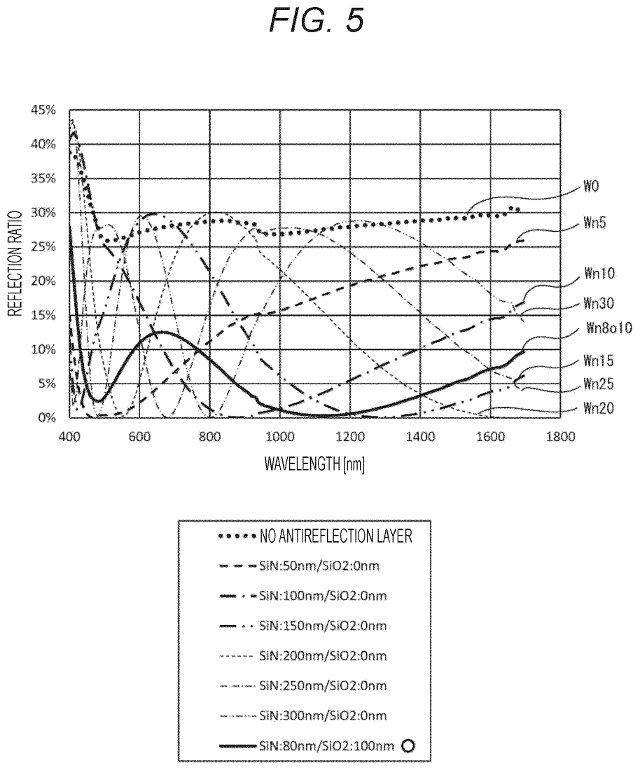

Next, a second film thickness condition will be described in which the film thickness of the first insulating layer 45 is changed within a range from zero nm to 300 nm and the film thickness of the second insulating layer 46 is set to zero nm. FIG. 5 is a graph depicting a calculation result of a wavelength and a reflection ratio of incident light entering the light receiving element 30 including an antireflection layer of the second film thickness condition. Note that, in FIG. 5, the waveform Wn8o10 having the preferred reflection ratio as in FIG. 4 is depicted.

In FIG. 5, seven waveforms WO, Wn5, Wn10, Wn15, Wn20, Wn25, and Wn30 are illustrated in which the film thickness of the first insulating layer 45 is changed from zero nm to 300 nm at 50 nm intervals. In these waveforms, similarly to the waveform depicted in FIG. 4, the reflection ratio increases or decreases according to the wavelength of the incident light. Therefore, it is difficult to suppress the reflection ratio in the visible light wavelength band and the infrared light wavelength band, under the second film thickness condition. That is, under this second film thickness condition, it is not possible for this antireflection layer to suppress the reflection at the wavelength of 400 nm to 1700 nm, and there is a wavelength band where the sensitivity is extremely dropped. On the other hand, the waveform Wn8o10 indicated by the solid line in FIG. 5 has a preferred reflection ratio for the waveform under the second film thickness condition.

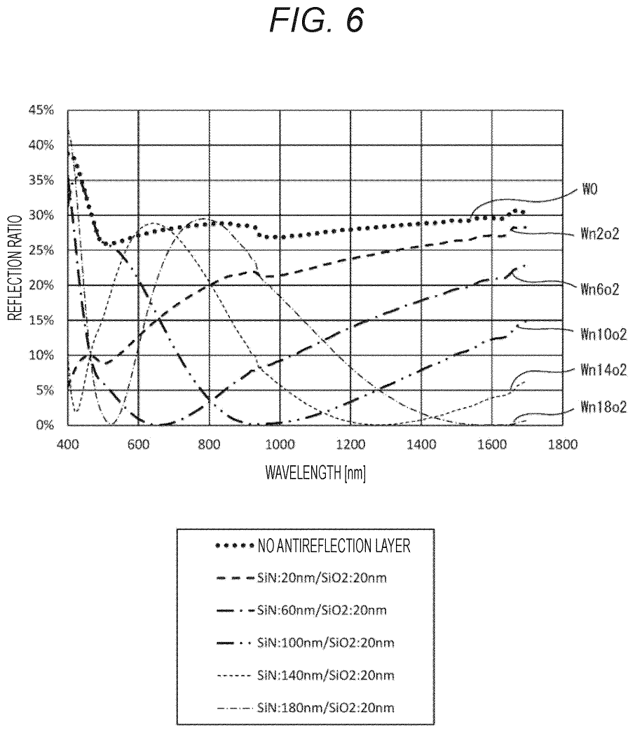

As described above, both in a case where the first insulating layer 45 includes a single layer as depicted in FIG. 4 and a case where the second insulating layer 46 includes a single layer as depicted in FIG. 5, it is not possible to lower the reflection ratio over a wide wavelength band from the visible light L1 to the infrared light L2. Therefore, a calculation result obtained by calculating the reflection ratio as changing the film thicknesses of the first insulating layer 45 and the second insulating layer 46 under a condition that the film thickness is equal to or more than 20 nm will be described with reference to FIGS. 6 to 11.

First, with reference to FIG. 6, a third film thickness condition will be described in which the film thickness of the first insulating layer 45 is changed within a range from 20 nm to 180 nm and the film thickness of the second insulating layer 46 is set to 20 nm. FIG. 6 is a graph depicting a calculation result of a wavelength and a reflection ratio of incident light entering the light receiving element 30 including an antireflection layer of the third film thickness condition.

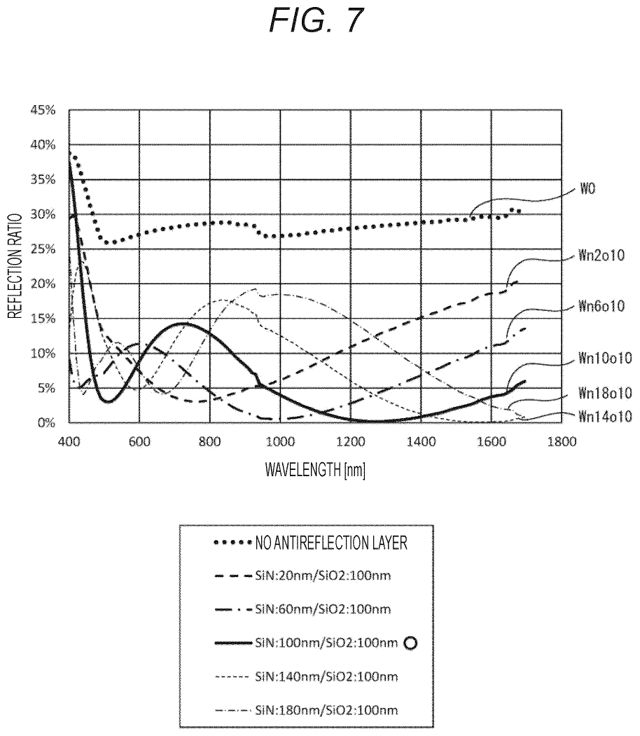

In FIG. 6, five waveforms Wn2o2, Wn6o2, Wn10o2, Wn14o2, and Wn18o2 are illustrated in which the film thickness of the first insulating layer 45 is changed from 20 nm to 180 nm at intervals of 40 nm and the film thickness of the second insulating layer 46 is set to 20 nm, as the third film thickness condition. Furthermore, in FIG. 6, a waveform WO in a case where both of the film thicknesses of the first insulating layer 45 and the second insulating layer 46 are set to zero nm and the antireflection layer is not provided is depicted (the same applies to FIGS. 7 to 11).

In the waveform under the third film thickness condition, the reflection ratio increases or decreases according to the wavelength of the incident light, similarly to the waveform depicted in FIG. 4. Therefore, under the third film thickness condition, it is difficult to suppress the reflection ratio in the visible light wavelength band and the infrared light wavelength band. That is, under this film thickness condition, it is not possible for this antireflection layer to suppress the reflection at the wavelength of 400 nm to 1700 nm, and there is a wavelength band where the sensitivity is extremely dropped. In particular, in the waveform under the third film thickness condition, there is a case where the reflection ratio is particularly increased in an infrared light band with a long wavelength, and the sensitivity is lowered.

Next, with reference to FIG. 7, a fourth film thickness condition will be described in which the film thickness of the first insulating layer 45 is changed within a range from 20 nm to 180 nm and the film thickness of the second insulating layer 46 is set to 100 nm. FIG. 7 is a graph depicting a calculation result of a wavelength and a reflection ratio of incident light entering the light receiving element 30 including an antireflection layer of the fourth film thickness condition.

In FIG. 7, five waveforms Wn2o10, Wn6o10, Wn10o10, Wn14o10, and Wn18o10 are depicted in which the film thickness of the first insulating layer 45 is changed from 20 nm to 180 nm at intervals of 40 nm and the film thickness of the second insulating layer 46 is set to 100 nm, as the fourth film thickness condition.

In the waveform under the fourth film thickness condition depicted in FIG. 7, the reflection ratio increases or decreases according to the wavelength of the incident light, similarly to the waveform depicted in the drawings described above. However, under the fourth film thickness condition, there is a case where the reflection ratio can be suppressed to be low in the wavelength band from the visible light L1 to the infrared light L2. That is, in the waveform Wn10o10 in which the film thicknesses of both the first insulating layer 45 and the second insulating layer 46 are set to 100 nm, the reflection ratio can be suppressed to 15% or less even at the peak in the visible light band and in a wavelength band, in which the reflection ratio increases, up to the wavelength of 1700 nm in the infrared light band. In this way, the reflection ratio can be suppressed to be low over a wide wavelength band from the visible light L1 to the infrared light L2.

Note that, here, it has been described that the waveform Wn10o10 in which the film thickness of both the first insulating layer 45 and the second insulating layer 46 is set to 100 nm is favorable in a point that the reflection ratio can be suppressed. However, the film thicknesses of the first insulating layer 45 and the second insulating layer 46 may be arbitrarily set depending on an application and a subject of the solid-state imaging device 100. For example, the waveform Wn6o10 in which the film thickness of the first insulating layer 45 is set to 60 nm and the film thickness of the second insulating layer 46 is set to 100 nm has a higher reflection ratio at the wavelength of 1700 nm than the waveform Wn10o10. However, this waveform Wn6o10 has a lower reflection ratio than the waveform Wn10o10 at the peak in the visible light band and around the wavelength of 1000 nm. In this way, by setting the film thicknesses of the first insulating layer 45 and the second insulating layer 46 according to the wavelength to be received for capturing an image, it is possible to perform appropriate imaging with high sensitivity according to an application and a subject.

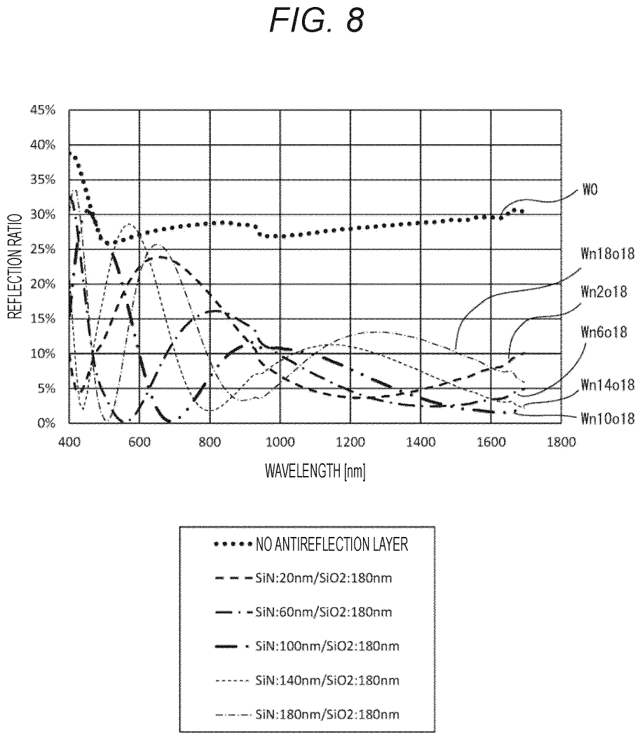

Next, with reference to FIG. 8, a fifth film thickness condition will be described in which the film thickness of the first insulating layer 45 is changed within a range from 20 nm to 180 nm and the film thickness of the second insulating layer 46 is set to 180 nm. FIG. 8 is a graph depicting a calculation result of a wavelength and a reflection ratio of incident light entering the light receiving element 30 including an antireflection layer of the fifth film thickness condition.

In FIG. 8, five waveforms Wn2o18, Wn6o18, Wn10o18, Wn14o18, and Wn18o18 are depicted in which the film thickness of the first insulating layer 45 is changed from 20 nm to 180 nm at intervals of 40 nm and the film thickness of the second insulating layer 46 is set to 180 nm, as the fourth film thickness condition.

In the waveform under the fifth film thickness condition, the reflection ratio increases or decreases according to the wavelength of the incident light, similarly to the waveform depicted in the drawings described above. Therefore, under the fifth film thickness condition, it is difficult to suppress the reflection ratio in the visible light wavelength band and the infrared light wavelength band. That is, under this film thickness condition, it is not possible for this antireflection layer to suppress the reflection at the wavelength of 400 nm to 1700 nm, and there is a wavelength band where the sensitivity is extremely dropped.

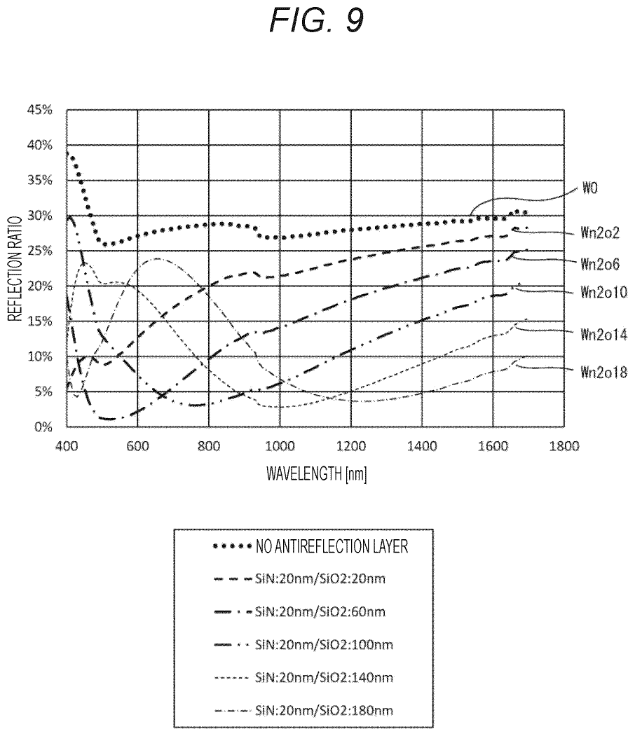

Subsequently, with reference to FIG. 9, a sixth film thickness condition will be described in which the film thickness of the first insulating layer 45 is set to 20 nm and the film thickness of the second insulating layer 46 is changed within a range from 20 nm to 180 nm. FIG. 9 is a graph depicting a calculation result of a wavelength and a reflection ratio of incident light entering the light receiving element 30 including an antireflection layer of the sixth film thickness condition.

In FIG. 9, five waveforms Wn2o2, Wn2o6, Wn2o10, Wn2o14, and Wn2o18 are depicted in which the film thickness of the first insulating layer 45 is set to 20 nm and the film thickness of the second insulating layer 46 is changed from 20 nm to 180 nm at intervals of 40 nm as the sixth film thickness condition.

In the waveform under the sixth film thickness condition, the reflection ratio increases or decreases according to the wavelength of the incident light, similarly to the waveform depicted in the drawings described above. Therefore, under the sixth film thickness condition, it is difficult to suppress the reflection ratio in the visible light wavelength band and the infrared light wavelength band. That is, under this film thickness condition, it is not possible for this antireflection layer to suppress the reflection at the wavelength of 400 nm to 1700 nm, and there is a wavelength band where the sensitivity is extremely dropped. In particular, in the waveform under the sixth film thickness condition, there is a case where the reflection ratio is particularly increased in an infrared light band with a long wavelength, and the sensitivity is lowered.

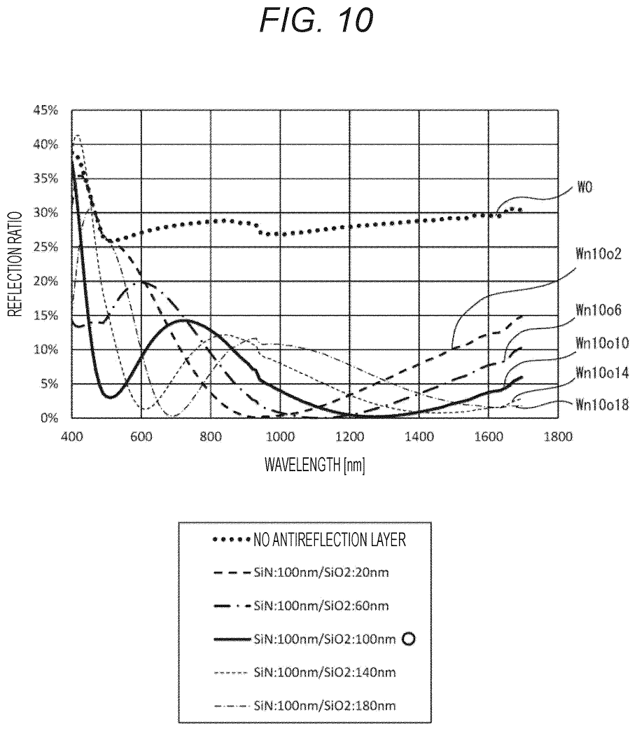

Subsequently, with reference to FIG. 10, a seventh film thickness condition will be described in which the film thickness of the first insulating layer 45 is set to 100 nm and the film thickness of the second insulating layer 46 is changed within a range from 20 nm to 180 nm. FIG. 10 is a graph depicting a calculation result of a wavelength and a reflection ratio of incident light entering the light receiving element 30 including an antireflection layer of the seventh film thickness condition.

In FIG. 10, five waveforms Wn10o2, Wn10o6, Wn10o10, Wn10o14, and Wn10o18 are depicted in which the film thickness of the first insulating layer 45 is set to 100 nm and the film thickness of the second insulating layer 46 is changed from 20 nm to 180 nm at intervals of 40 nm as the seventh film thickness condition.

In the waveform under the seventh film thickness condition depicted in FIG. 10, the reflection ratio increases or decreases according to the wavelength of the incident light, similarly to the waveform depicted in the drawings described above. In FIG. 10, as in FIG. 7, the waveform Wn10o10 in which the film thickness of both of the first insulating layer 45 and the second insulating layer 46 is set to 100 nm can lower the reflection ratio in a wide wavelength band and can suppress the reflection ratio to be equal to or less than 15%. Furthermore, when the waveform in FIG. 10 is compared with, for example, the waveform in FIG. 9, the reflection ratio in the infrared light band can be suppressed to be considerably low.

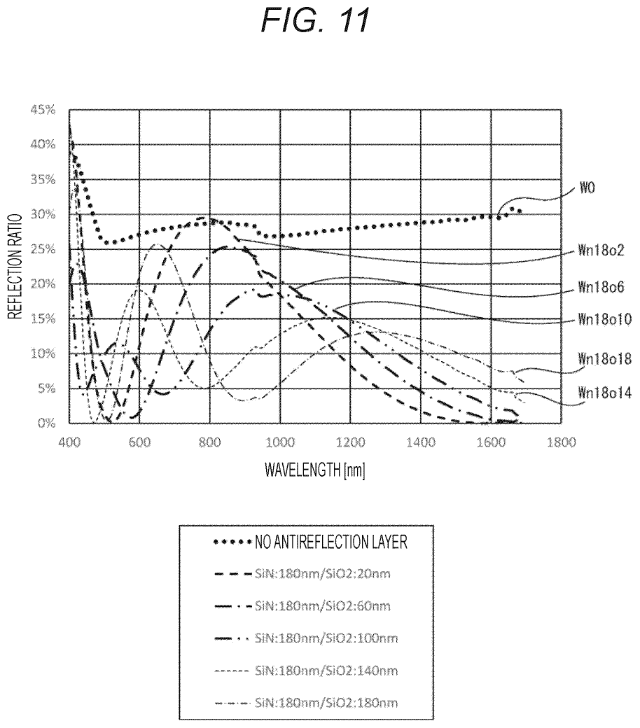

Finally, with reference to FIG. 11, an eighth film thickness condition will be described in which the film thickness of the first insulating layer 45 is set to 180 nm and the film thickness of the second insulating layer 46 is changed within a range from 20 nm to 180 nm. FIG. 11 is a graph depicting a calculation result of a wavelength and a reflection ratio of incident light entering the light receiving element 30 including an antireflection layer of the eighth film thickness condition.

In FIG. 11, five waveforms Wn18o2, Wn18o6, Wn18o10, Wn18o14, and Wn18o18 are depicted in which the film thickness of the first insulating layer 45 is set to 180 nm and the film thickness of the second insulating layer 46 is changed from 20 nm to 180 nm at intervals of 40 nm as the eighth film thickness condition.

In the waveform under the eighth film thickness condition, the reflection ratio increases or decreases according to the wavelength of the incident light, similarly to the waveform depicted in the drawings described above. Therefore, under the eighth film thickness condition, it is difficult to suppress the reflection ratio in the visible light wavelength band and the infrared light wavelength band. That is, under this film thickness condition, it is not possible for this antireflection layer to suppress the reflection at the wavelength of 400 nm to 1700 nm, and there is a wavelength band where the sensitivity is extremely dropped. In particular, in the waveform under the eighth film thickness condition, the reflection ratio increases in the wavelength band from 600 nm to 1000 nm, and the sensitivity in the visible light band is lowered.

Here, film thickness setting of the first insulating layer 45 and the second insulating layer 46 that may lower the reflection ratio in a wide wavelength band will be described, by comparing FIGS. 10 and 11. On the basis of the calculation result depicted in FIG. 10, by setting the film thicknesses to be sufficiently thick while setting the film thicknesses of the first insulating layer 45 and the second insulating layer 46 to be close values, it is possible to suppress the reflection ratio to be low in a wide wavelength band. However, in the waveform Wn18o18 in which the film thicknesses of both of the first insulating layer 45 and the second insulating layer 46 are set to be equal to 180 nm depicted in FIG. 11, the reflection ratio is high in the visible light wavelength band. Therefore, it is understood that it is not sufficient to set the film thicknesses of the first insulating layer 45 and the second insulating layer 46 to be close values so as to have a sufficient thickness.

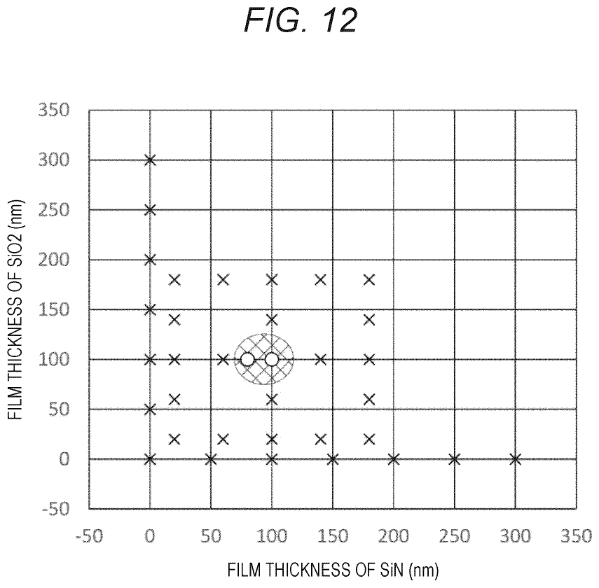

Therefore, a relationship between the film thickness conditions of the first insulating layer 45 and the second insulating layer 46 and the antireflection performance will be described. For all the film thickness conditions depicted in FIGS. 4 to 11, a relationship between the film thicknesses of the insulating layers 45 and 46 and the antireflection performance will be described. FIG. 12 is a graph depicting a relationship between a film thickness of an insulating layer and an evaluation result of the antireflection performance. In FIG. 12, a condition with a high antireflection performance is depicted using a circle, and a condition with a high antireflection performance is depicted using x.

As depicted in FIG. 12, it is not necessary to only simply thicken the first insulating layer 45 and the second insulating layer 46 to have film thicknesses close to each other, and more preferable film thickness setting exist, as the waveform Wn8o10 depicted in FIGS. 4 and 5 or the waveform Wn10o10 depicted in FIGS. 7 and 10. Furthermore, as can be seen from the waveforms depicted in the drawings described above, when the film thickness is gradually increased or decreased, the waveform gradually moves in a wavelength direction and a reflection ratio direction. Therefore, it can be seen that, under a film thickness condition close to the insulating layer having an excellent reflection ratio, such as the waveform Wn8o10 or the waveform Wn10o10, the reflection ratio is excellent even if the range of the wavelength of the incident light is wide. Therefore, in FIG. 12, a region where the reflection ratio is considered to be good is hatched.

As can be seen from the above description, under the preconditions described above, by setting the film thickness of the first insulating layer 45 to 70 nm to 120 nm and the film thickness of the second insulating layer 46 to 80 nm to 120 nm, it is possible to prevent the reflection of the incident light over a wide wavelength range from the visible light to the infrared light. However, the reflection ratio and the waveform with the wavelength of the incident light are the calculation results based on the above calculation conditions and affected by the material or the film thickness of each layer such as the photoelectric conversion layer 41 or the semiconductor layer 44. Therefore, the film thicknesses of the first insulating layer 45 and the second insulating layer 46 may be appropriately set on the basis of the material or the film thickness of each layer such as the photoelectric conversion layer 41 or the semiconductor layer 44 set depending on the application, the subject, or the like.

As described above, according to the light receiving element 30 according to the first embodiment, by using the antireflection layer including the first insulating layer 45 containing silicon nitride and the second insulating layer 46 containing silicon oxide, the reflection of the incident light can be prevented over the wide wavelength range from the visible light L1 to the infrared light L2.

Furthermore, since the antireflection layer according to the present embodiment has two layers including the first insulating layer 45 and the second insulating layer 46, the antireflection layer can be manufactured in a simple process, and it is possible to inexpensively form an antireflection layer with a high reflection prevention effect. Furthermore, the first insulating layer 45 containing silicon nitride and the second insulating layer 46 containing silicon oxide can be formed by a general-purpose semiconductor manufacturing process, and an antireflection layer with a high reflection prevention effect can be inexpensively formed. Furthermore, the via used to apply the bias voltage Va can be easily molded.

### SECOND EMBODIMENT

FIG. 13 is a cross-sectional view depicting a cross-sectional structure of a pixel according to a second embodiment. A light receiving element 30 according to the present embodiment is similar to the configuration according to the first embodiment, except that a transparent electrode layer 49 arranged between a semiconductor layer 44 and a first insulating layer 45 is further included.

The transparent electrode layer 49 functions as an upper electrode on an upper side of electrodes that vertically sandwich a photoelectric conversion layer 41, and a bias voltage Va is applied. Furthermore, a film thickness of the transparent electrode layer 49 is formed to be, for example, about 10 nm. As the transparent electrode layer 49, for example, a material such as indium tin oxide (ITO) or ITiO (In₂O₃-TiO₂) that can transmit visible light L1 and infrared light L2 can be used.

The light receiving element 30 according to the second embodiment can achieve effects similar to those of the light receiving element 30 according to the first embodiment.

Furthermore, since this light receiving element 30 includes the common transparent electrode layer 49, as compared with the first embodiment, the bias voltage Va can be more stably applied to a cathode side of a photoelectric conversion element included in each light receiving element 30.

### THIRD EMBODIMENT

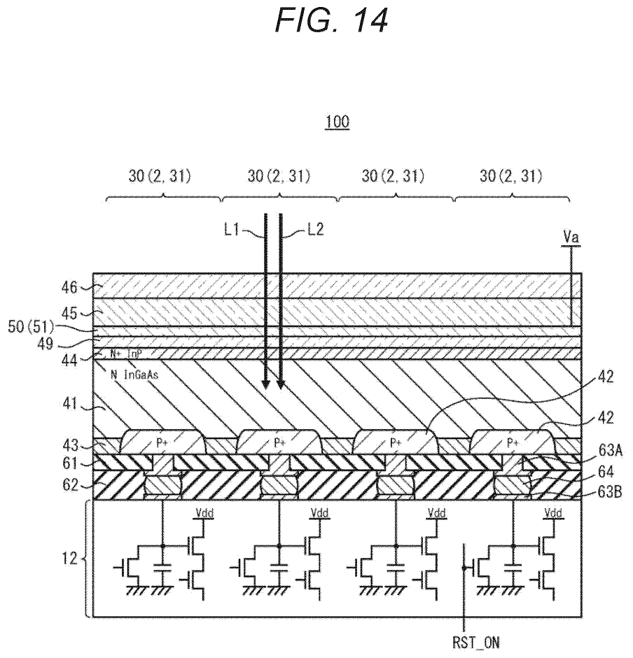

FIG. 14 is a cross-sectional view depicting a cross-sectional structure of a pixel according to a third embodiment. A light receiving element 30 according to the present embodiment is similar to the configuration according to the second embodiment except that a third insulating layer 50 arranged between a transparent electrode layer 49 and a first insulating layer 45 is further included. The third insulating layer 50 contains silicon oxide and has a film thickness equal to or less than 10 nm. Since this third insulating layer 50 is formed to be sufficiently thinner than the first insulating layer 45 and a second insulating layer 46, the third insulating layer 50 hardly affects a reflection ratio of the light receiving element 30.

The light receiving element 30 according to the third embodiment can achieve effects similar to those of the light receiving element 30 according to the second embodiment. Furthermore, since this light receiving element 30 includes the third insulating layer 50 on the transparent electrode layer 49, it is possible to prevent deterioration in characteristics of the transparent electrode layer 49.

Note that the third insulating layer 50 may have a configuration further including the third insulating layer 50 that contains silicon nitride and has the film thickness equal to or less than 10 nm, instead of the configuration containing silicon oxide.

Note that a configuration may be used that includes a fourth insulating layer 51 arranged between a semiconductor layer 44 and the first insulating layer 45, without providing the transparent electrode layer 49. In this case, the fourth insulating layer 51 contains silicon oxide.

### FOURTH EMBODIMENT

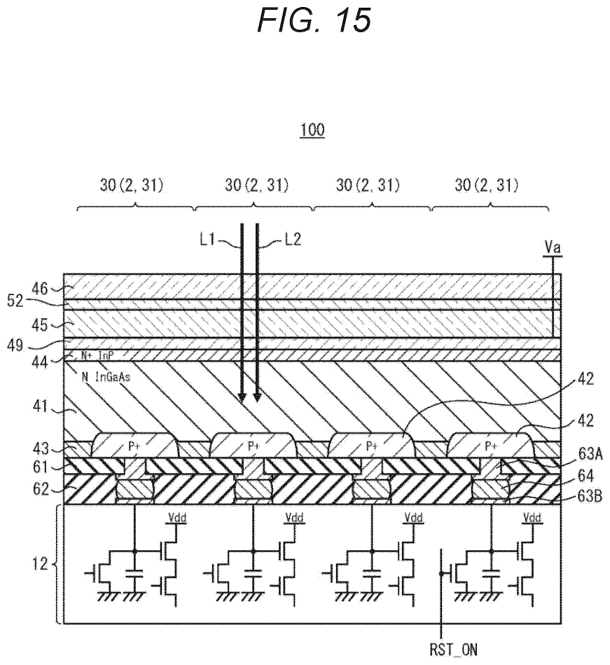

FIG. 15 is a cross-sectional view depicting a cross-sectional structure of a pixel according to a fourth embodiment. A light receiving element 30 according to the present embodiment is similar to the configuration according to the second embodiment except that a fifth insulating layer 52 arranged between a first insulating layer 45 and a second insulating layer 46 is further included. The fifth insulating layer 52 contains at least one of aluminum oxide, magnesium oxide, or titanium oxide and has a film thickness equal to or less than 10 nm. The fifth insulating layer 52 is a transparent insulating film.

The light receiving element 30 according to the fourth embodiment can achieve effects similar to those of the light receiving element 30 according to the second embodiment.

Furthermore, this light receiving element 30 can alleviate a stress between the first insulating layer 45 and the second insulating layer 46 by the fifth insulating layer 52.

Note that the fifth insulating layer 52 may be arranged between a transparent electrode layer 49 and the first insulating layer 45. This can also alleviate the stress between these layers.

### FIFTH EMBODIMENT

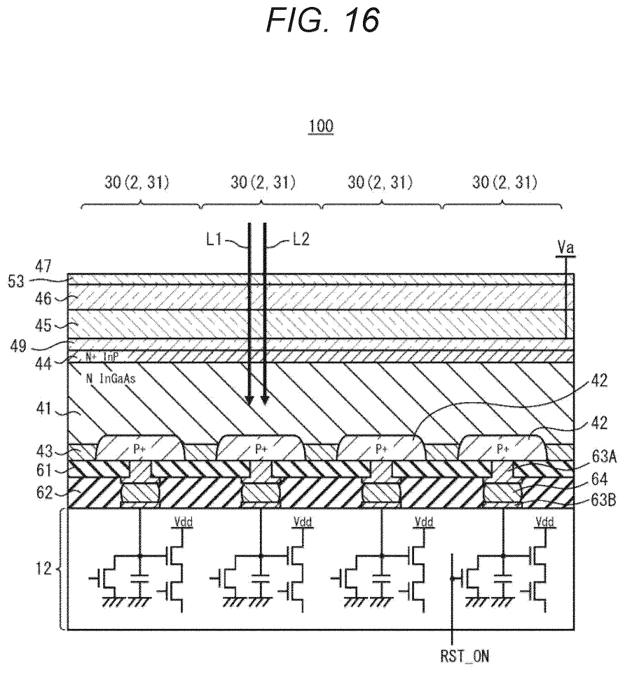

FIG. 16 is a cross-sectional view depicting a cross-sectional structure of a pixel according to a fifth embodiment. A light receiving element 30 according to the present embodiment is similar to the configuration according to the second embodiment except that a sixth insulating layer 53 arranged on a light incident surface side than a second insulating layer 46 is further included. The sixth insulating layer 53 contains at least one of silicon nitride, aluminum oxide, magnesium oxide, or titanium oxide and has a film thickness equal to or less than 10 nm. The sixth insulating layer 53 is a transparent insulating film.

The light receiving element 30 according to the fifth embodiment can achieve effects similar to those of the light receiving element 30 according to the second embodiment. Furthermore, this light receiving element 30 can obtain a stress alleviation effect by the sixth insulating layer 53.

### SIXTH EMBODIMENT

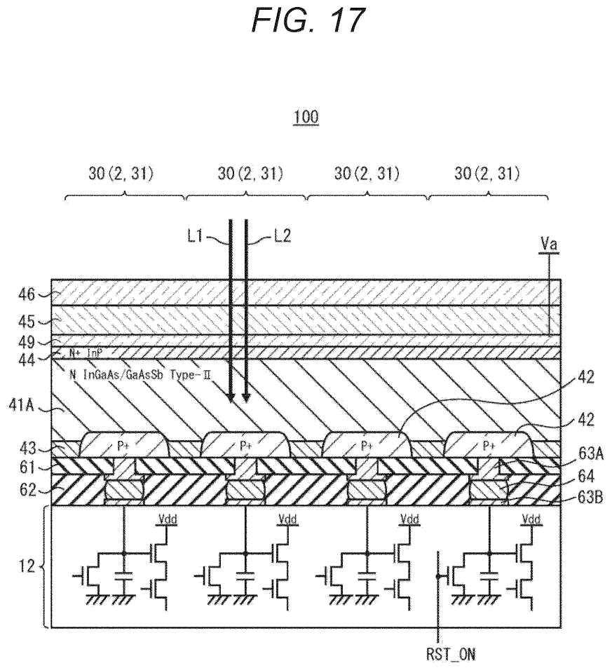

FIG. 17 is a cross-sectional view depicting a cross-sectional structure of a pixel according to a sixth embodiment. A light receiving element 30 according to the present embodiment is similar to the configuration according to the first embodiment except that a photoelectric conversion layer 41A has a layer structure in which a first layer containing InGaAs and a second layer containing GaAsSb are alternately laminated a plurality of times.

As the photoelectric conversion layer 41A in this embodiment, the layer structure in which the first layer containing InGaAs and the second layer containing GaAsSb are alternately laminated is referred to as a type 2 structure. According to the photoelectric conversion layer 41 having such a configuration, for example, it is possible to detect infrared light L2 with a long wavelength from 2400 nm to 2600 nm.

The light receiving element 30 according to the sixth embodiment can achieve effects similar to those of the light receiving element 30 according to the first embodiment.

Furthermore, in the light receiving element 30, it is possible to detect incident light in a wider range by detecting the infrared light L2 with the long wavelength by the photoelectric conversion layer 41A of the type 2 structure.

### SEVENTH EMBODIMENT

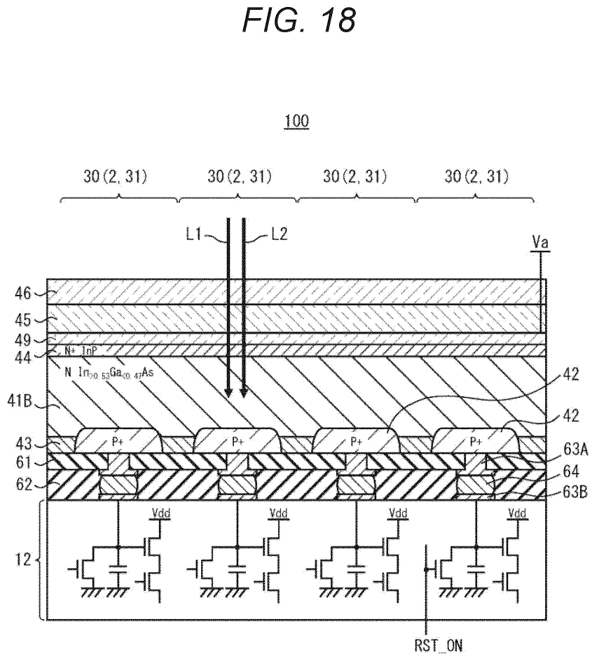

FIG. 18 is a cross-sectional view depicting a cross-sectional structure of a pixel according to a seventh embodiment. A light receiving element 30 according to the present embodiment is similar to the configuration according to the first embodiment except that a photoelectric conversion layer 41B has a distorted InGaAs structure containing InₓGa₍₁₋ₓ₎As (x is equal to or more than 0.53).

The light receiving element 30 according to the sixth embodiment can achieve effects similar to those of the light receiving element 30 according to the first embodiment by the photoelectric conversion layer 41B. Furthermore, the light receiving element 30 can detect incident light in a wider range by detecting infrared light L2 with a long wavelength with the distorted InGaAs structure.

### APPLICATION EXAMPLE

The technology according to the present disclosure can be applied to various products. For example, the technology according to the present disclosure may also be realized as a device mounted on any type of mobile body such as an automobile, an electric automobile, a hybrid electric automobile, a motorcycle, a bicycle, a personal mobility, an airplane, a drone, a ship, a robot, a building machine, or an agricultural machine (tractor).

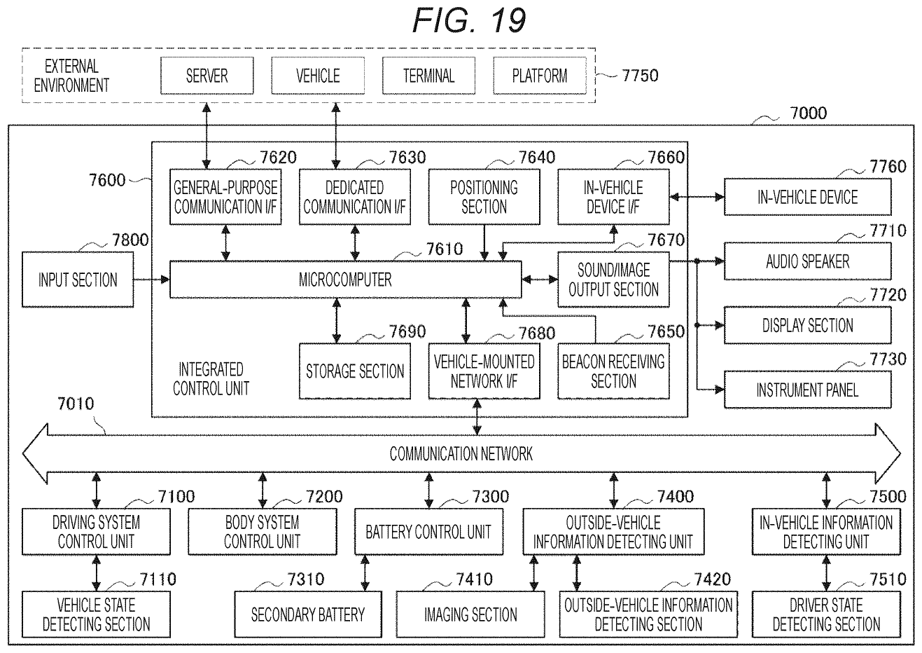

FIG. 19 is a block diagram depicting a schematic configuration example of a vehicle control system 7000 as an example of a mobile body control system to which the technology according to the present disclosure may be applied. The vehicle control system 7000 includes a plurality of electronic control units connected to each other via a communication network 7010. In the example depicted in FIG. 19, the vehicle control system 7000 includes a driving system control unit 7100, a body system control unit 7200, a battery control unit 7300, an outside-vehicle information detecting unit 7400, an in-vehicle information detecting unit 7500, and an integrated control unit 7600. The communication network 7010 connecting the plurality of control units to each other may, for example, be a vehicle-mounted communication network compliant with an arbitrary standard such as controller area network (CAN), local interconnect network (LIN), local area network (LAN), FlexRay (registered trademark), or the like.

Each of the control units includes: a microcomputer that performs arithmetic processing according to various kinds of programs; a storage section that stores the programs executed by the microcomputer, parameters used for various kinds of operations, or the like; and a driving circuit that drives various kinds of control target devices. Each of the control units further includes: a network interface (I/F) for performing communication with other control units via the communication network 7010; and a communication I/F for performing communication with a device, a sensor, or the like within and without the vehicle by wire communication or radio communication. A functional configuration of the integrated control unit 7600 depicted in FIG. 19 includes a microcomputer 7610, a general-purpose communication I/F 7620, a dedicated communication I/F 7630, a positioning section 7640, a beacon receiving section 7650, an in-vehicle device I/F 7660, a sound/image output section 7670, a vehicle-mounted network I/F 7680, and a storage section 7690. The other control units similarly include a microcomputer, a communication I/F, a storage section, and the like.

The driving system control unit 7100 controls the operation of devices related to the driving system of the vehicle in accordance with various kinds of programs. For example, the driving system control unit 7100 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like. The driving system control unit 7100 may have a function as a control device of an antilock brake system (ABS), electronic stability control (ESC), or the like.

The driving system control unit 7100 is connected with a vehicle state detecting section 7110. The vehicle state detecting section 7110, for example, includes at least one of a gyro sensor that detects the angular velocity of axial rotational movement of a vehicle body, an acceleration sensor that detects the acceleration of the vehicle, and sensors for detecting an amount of operation of an accelerator pedal, an amount of operation of a brake pedal, the steering angle of a steering wheel, an engine speed or the rotational speed of wheels, and the like. The driving system control unit 7100 performs arithmetic processing using a signal input from the vehicle state detecting section 7110, and controls the internal combustion engine, the driving motor, an electric power steering device, the brake device, and the like.

The body system control unit 7200 controls the operation of various kinds of devices provided to the vehicle body in accordance with various kinds of programs. For example, the body system control unit 7200 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 7200. The body system control unit 7200 receives these input radio waves or signals, and controls a door lock device, the power window device, the lamps, or the like of the vehicle.

The battery control unit 7300 controls a secondary battery 7310, which is a power supply source for the driving motor, in accordance with various kinds of programs. For example, the battery control unit 7300 is supplied with information about a battery temperature, a battery output voltage, an amount of charge remaining in the battery, or the like from a battery device including the secondary battery 7310. The battery control unit 7300 performs arithmetic processing using these signals, and performs control for regulating the temperature of the secondary battery 7310 or controls a cooling device provided to the battery device or the like.

The outside-vehicle information detecting unit 7400 detects information about the outside of the vehicle including the vehicle control system 7000. For example, the outside-vehicle information detecting unit 7400 is connected with at least one of an imaging section 7410 and an outside-vehicle information detecting section 7420. The imaging section 7410 includes at least one of a time-of-flight (ToF) camera, a stereo camera, a monocular camera, an infrared camera, and other cameras. The outside-vehicle information detecting section 7420, for example, includes at least one of an environmental sensor for detecting current atmospheric conditions or weather conditions and a peripheral information detecting sensor for detecting another vehicle, an obstacle, a pedestrian, or the like on the periphery of the vehicle including the vehicle control system 7000.

The environmental sensor, for example, may be at least one of a rain drop sensor detecting rain, a fog sensor detecting a fog, a sunshine sensor detecting a degree of sunshine, and a snow sensor detecting a snowfall. The peripheral information detecting sensor may be at least one of an ultrasonic sensor, a radar device, and a LIDAR device (Light detection and Ranging device, or Laser imaging detection and ranging device). Each of the imaging section 7410 and the outside-vehicle information detecting section 7420 may be provided as an independent sensor or device, or may be provided as a device in which a plurality of sensors or devices are integrated.

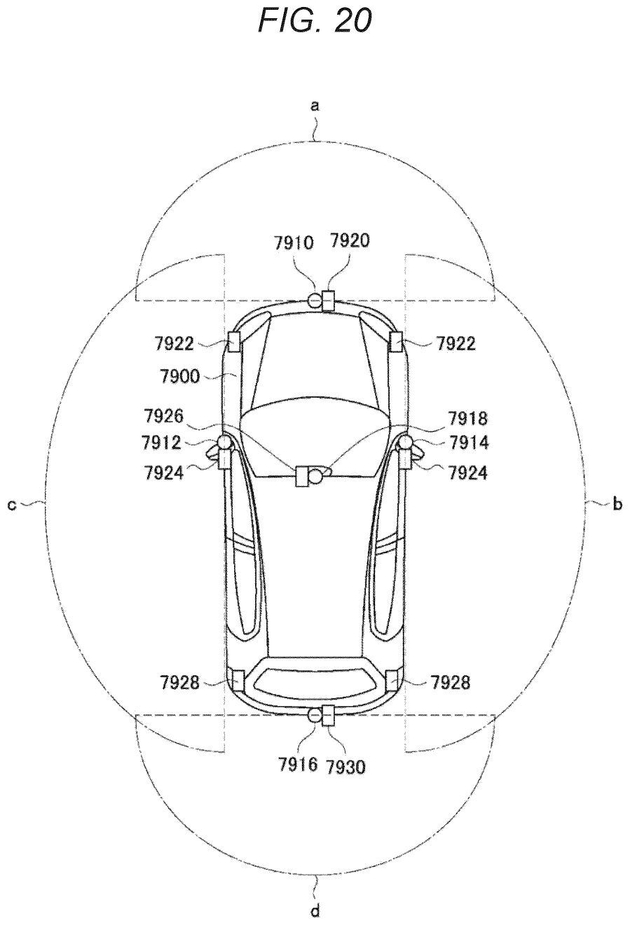

Here, FIG. 20 depicts an example of installation positions of the imaging section 7410 and the outside-vehicle information detecting section 7420. Imaging sections 7910, 7912, 7914, 7916, and 7918 are, for example, disposed at at least one of positions on a front nose, sideview mirrors, a rear bumper, and a back door of the vehicle 7900 and a position on an upper portion of a windshield within the interior of the vehicle. The imaging section 7910 provided to the front nose and the imaging section 7918 provided to the upper portion of the windshield within the interior of the vehicle obtain mainly an image of the front of the vehicle 7900. The imaging sections 7912 and 7914 provided to the sideview mirrors obtain mainly an image of the sides of the vehicle 7900. The imaging section 7916 provided to the rear bumper or the back door obtains mainly an image of the rear of the vehicle 7900. The imaging section 7918 provided to the upper portion of the windshield within the interior of the vehicle is used mainly to detect a preceding vehicle, a pedestrian, an obstacle, a signal, a traffic sign, a lane, or the like.

Incidentally, FIG. 20 depicts an example of photographing ranges of the respective imaging sections 7910, 7912, 7914, and 7916. An imaging range a represents the imaging range of the imaging section 7910 provided to the front nose. Imaging ranges b and c respectively represent the imaging ranges of the imaging sections 7912 and 7914 provided to the sideview mirrors. An imaging range d represents the imaging range of the imaging section 7916 provided to the rear bumper or the back door. A bird's-eye image of the vehicle 7900 as viewed from above can be obtained by superimposing image data imaged by the imaging sections 7910, 7912, 7914, and 7916, for example.

Outside-vehicle information detecting sections 7920, 7922, 7924, 7926, 7928, and 7930 provided to the front, rear, sides, and corners of the vehicle 7900 and the upper portion of the windshield within the interior of the vehicle may be, for example, an ultrasonic sensor or a radar device. The outside-vehicle information detecting sections 7920, 7926, and 7930 provided to the front nose of the vehicle 7900, the rear bumper, the back door of the vehicle 7900, and the upper portion of the windshield within the interior of the vehicle may be a LIDAR device, for example. These outside-vehicle information detecting sections 7920 to 7930 are used mainly to detect a preceding vehicle, a pedestrian, an obstacle, or the like.

Returning to FIG. 19, the description will be continued. The outside-vehicle information detecting unit 7400 makes the imaging section 7410 image an image of the outside of the vehicle, and receives imaged image data. In addition, the outside-vehicle information detecting unit 7400 receives detection information from the outside-vehicle information detecting section 7420 connected to the outside-vehicle information detecting unit 7400. In a case where the outside-vehicle information detecting section 7420 is an ultrasonic sensor, a radar device, or a LIDAR device, the outside-vehicle information detecting unit 7400 transmits an ultrasonic wave, an electromagnetic wave, or the like, and receives information of a received reflected wave. On the basis of the received information, the outside-vehicle information detecting unit 7400 may perform processing of detecting an object such as a human, a vehicle, an obstacle, a sign, a character on a road surface, or the like, or processing of detecting a distance thereto. The outside-vehicle information detecting unit 7400 may perform environment recognition processing of recognizing a rainfall, a fog, road surface conditions, or the like on the basis of the received information. The outside-vehicle information detecting unit 7400 may calculate a distance to an object outside the vehicle on the basis of the received information.

In addition, on the basis of the received image data, the outside-vehicle information detecting unit 7400 may perform image recognition processing of recognizing a human, a vehicle, an obstacle, a sign, a character on a road surface, or the like, or processing of detecting a distance thereto. The outside-vehicle information detecting unit 7400 may subject the received image data to processing such as distortion correction, alignment, or the like, and combine the image data imaged by a plurality of different imaging sections 7410 to generate a bird's-eye image or a panoramic image. The outside-vehicle information detecting unit 7400 may perform viewpoint conversion processing using the image data imaged by the imaging section 7410 including the different imaging parts.

The in-vehicle information detecting unit 7500 detects information about the inside of the vehicle. The in-vehicle information detecting unit 7500 is, for example, connected with a driver state detecting section 7510 that detects the state of a driver. The driver state detecting section 7510 may include a camera that images the driver, a biosensor that detects biological information of the driver, a microphone that collects sound within the interior of the vehicle, or the like. The biosensor is, for example, disposed in a seat surface, the steering wheel, or the like, and detects biological information of an occupant sitting in a seat or the driver holding the steering wheel. On the basis of detection information input from the driver state detecting section 7510, the in-vehicle information detecting unit 7500 may calculate a degree of fatigue of the driver or a degree of concentration of the driver, or may determine whether the driver is dozing. The in-vehicle information detecting unit 7500 may subject an audio signal obtained by the collection of the sound to processing such as noise canceling processing or the like.

The integrated control unit 7600 controls general operation within the vehicle control system 7000 in accordance with various kinds of programs. The integrated control unit 7600 is connected with an input section 7800. The input section 7800 is implemented by a device capable of input operation by an occupant, such, for example, as a touch panel, a button, a microphone, a switch, a lever, or the like. The integrated control unit 7600 may be supplied with data obtained by voice recognition of voice input through the microphone. The input section 7800 may, for example, be a remote control device using infrared rays or other radio waves, or an external connecting device such as a mobile telephone, a personal digital assistant (PDA), or the like that supports operation of the vehicle control system 7000. The input section 7800 may be, for example, a camera. In that case, an occupant can input information by gesture. Alternatively, data may be input which is obtained by detecting the movement of a wearable device that an occupant wears. Further, the input section 7800 may, for example, include an input control circuit or the like that generates an input signal on the basis of information input by an occupant or the like using the above-described input section 7800, and which outputs the generated input signal to the integrated control unit 7600. An occupant or the like inputs various kinds of data or gives an instruction for processing operation to the vehicle control system 7000 by operating the input section 7800.

The storage section 7690 may include a read only memory (ROM) that stores various kinds of programs executed by the microcomputer and a random access memory (RAM) that stores various kinds of parameters, operation results, sensor values, or the like. In addition, the storage section 7690 may be implemented by a magnetic storage device such as a hard disc drive (HDD) or the like, a semiconductor storage device, an optical storage device, a magneto-optical storage device, or the like.

The general-purpose communication I/F 7620 is a communication I/F used widely, which communication I/F mediates communication with various apparatuses present in an external environment 7750. The general-purpose communication I/F 7620 may implement a cellular communication protocol such as global system for mobile communications (GSM (registered trademark)), worldwide interoperability for microwave access (WiMAX (registered trademark)), long term evolution (LTE (registered trademark)), LTE-advanced (LTE-A), or the like, or another wireless communication protocol such as wireless LAN (referred to also as wireless fidelity (Wi-Fi (registered trademark)), Bluetooth (registered trademark), or the like. The general-purpose communication I/F 7620 may, for example, connect to an apparatus (for example, an application server or a control server) present on an external network (for example, the Internet, a cloud network, or a company-specific network) via a base station or an access point. In addition, the general-purpose communication I/F 7620 may connect to a terminal present in the vicinity of the vehicle (which terminal is, for example, a terminal of the driver, a pedestrian, or a store, or a machine type communication (MTC) terminal) using a peer to peer (P2P) technology, for example.

The dedicated communication I/F 7630 is a communication I/F that supports a communication protocol developed for use in vehicles. The dedicated communication I/F 7630 may implement a standard protocol such, for example, as wireless access in vehicle environment (WAVE), which is a combination of institute of electrical and electronic engineers (IEEE) 802.11p as a lower layer and IEEE 1609 as a higher layer, dedicated short range communications (DSRC), or a cellular communication protocol. The dedicated communication I/F 7630 typically carries out V2X communication as a concept including one or more of communication between a vehicle and a vehicle (Vehicle to Vehicle), communication between a road and a vehicle (Vehicle to Infrastructure), communication between a vehicle and a home (Vehicle to Home), and communication between a pedestrian and a vehicle (Vehicle to Pedestrian).

The positioning section 7640, for example, performs positioning by receiving a global navigation satellite system (GNSS) signal from a GNSS satellite (for example, a GPS signal from a global positioning system (GPS) satellite), and generates positional information including the latitude, longitude, and altitude of the vehicle. Incidentally, the positioning section 7640 may identify a current position by exchanging signals with a wireless access point, or may obtain the positional information from a terminal such as a mobile telephone, a personal handyphone system (PHS), or a smart phone that has a positioning function.

The beacon receiving section 7650, for example, receives a radio wave or an electromagnetic wave transmitted from a radio station installed on a road or the like, and thereby obtains information about the current position, congestion, a closed road, a necessary time, or the like. Incidentally, the function of the beacon receiving section 7650 may be included in the dedicated communication I/F 7630 described above.

The in-vehicle device I/F 7660 is a communication interface that mediates connection between the microcomputer 7610 and various in-vehicle devices 7760 present within the vehicle. The in-vehicle device I/F 7660 may establish wireless connection using a wireless communication protocol such as wireless LAN, Bluetooth (registered trademark), near field communication (NFC), or wireless universal serial bus (WUSB). In addition, the in-vehicle device I/F 7660 may establish wired connection by universal serial bus (USB), high-definition multimedia interface (HDMI (registered trademark)), mobile high-definition link (MHL), or the like via a connection terminal (and a cable if necessary) not depicted in the figures. The in-vehicle devices 7760 may, for example, include at least one of a mobile device and a wearable device possessed by an occupant and an information device carried into or attached to the vehicle. The in-vehicle devices 7760 may also include a navigation device that searches for a path to an arbitrary destination. The in-vehicle device I/F 7660 exchanges control signals or data signals with these in-vehicle devices 7760.

The vehicle-mounted network I/F 7680 is an interface that mediates communication between the microcomputer 7610 and the communication network 7010. The vehicle-mounted network I/F 7680 transmits and receives signals or the like in conformity with a predetermined protocol supported by the communication network 7010.

The microcomputer 7610 of the integrated control unit 7600 controls the vehicle control system 7000 in accordance with various kinds of programs on the basis of information obtained via at least one of the general-purpose communication I/F 7620, the dedicated communication I/F 7630, the positioning section 7640, the beacon receiving section 7650, the in-vehicle device I/F 7660, and the vehicle-mounted network I/F 7680. For example, the microcomputer 7610 may calculate a control target value for the driving force generating device, the steering mechanism, or the braking device on the basis of the obtained information about the inside and outside of the vehicle, and output a control command to the driving system control unit 7100. For example, the microcomputer 7610 may perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like. In addition, the microcomputer 7610 may perform cooperative control intended for automated driving, which makes the vehicle to travel automatedly without depending on the operation of the driver, or the like, by controlling the driving force generating device, the steering mechanism, the braking device, or the like on the basis of the obtained information about the surroundings of the vehicle.

The microcomputer 7610 may generate three-dimensional distance information between the vehicle and an object such as a surrounding structure, a person, or the like, and generate local map information including information about the surroundings of the current position of the vehicle, on the basis of information obtained via at least one of the general-purpose communication I/F 7620, the dedicated communication I/F 7630, the positioning section 7640, the beacon receiving section 7650, the in-vehicle device I/F 7660, and the vehicle-mounted network I/F 7680. In addition, the microcomputer 7610 may predict danger such as collision of the vehicle, approaching of a pedestrian or the like, an entry to a closed road, or the like on the basis of the obtained information, and generate a warning signal. The warning signal may, for example, be a signal for producing a warning sound or lighting a warning lamp.

The sound/image output section 7670 transmits an output signal of at least one of a sound and an image to an output device capable of visually or auditorily notifying information to an occupant of the vehicle or the outside of the vehicle. In the example in FIG. 19, an audio speaker 7710, a display section 7720, and an instrument panel 7730 are depicted as examples of the output device. The display section 7720 may, for example, include at least one of an on-board display and a head-up display. The display section 7720 may have an augmented reality (AR) display function. The output device may be other than these devices, and may be another device such as headphones, a wearable device such as an eyeglass type display worn by an occupant or the like, a projector, a lamp, or the like. In a case where the output device is a display device, the display device visually displays results obtained by various kinds of processing performed by the microcomputer 7610 or information received from another control unit in various forms such as text, an image, a table, a graph, or the like. In addition, in a case where the output device is an audio output device, the audio output device converts an audio signal constituted of reproduced audio data or sound data or the like into an analog signal, and auditorily outputs the analog signal.

Note that, in the example depicted in FIG. 19, at least two control units connected through the communication network 7010 may be integrated as one control unit. Alternatively, each individual control unit may include a plurality of control units. Further, the vehicle control system 7000 may include another control unit not depicted in the figures. In addition, part or the whole of the functions performed by one of the control units in the above description may be assigned to another control unit. That is, predetermined arithmetic processing may be performed by any of the control units as long as information is transmitted and received via the communication network 7010. Similarly, a sensor or a device connected to one of the control units may be connected to another control unit, and a plurality of control units may mutually transmit and receive detection information via the communication network 7010.

Note that the present technology can have the following configurations.
(1) A light receiving element including:
a photoelectric conversion layer containing a compound semiconductor material or an organic material;
a semiconductor layer arranged on a light incident surface side than the photoelectric conversion layer, containing a compound semiconductor material that prevents recombination of charges generated by photoelectric conversion by the photoelectric conversion layer, and having a film thickness thinner than the photoelectric conversion layer;
a first insulating layer arranged on the light incident surface side than the semiconductor layer, containing silicon nitride, and having a lower refractive index than the semiconductor layer; and
a second insulating layer arranged on the light incident surface side than the first insulating layer, containing silicon oxide, and having a lower refractive index than the first insulating layer.
(2) The light receiving element according to (1), in which a plurality of layers including the semiconductor layer, the first insulating layer, and the second insulating layer arranged on the light incident surface side from the photoelectric conversion layer has a smaller refractive index, as approaching a light incident surface.
(3) The light receiving element according to (1) or (2), further including: an antireflection layer arranged on the light incident surface side than the semiconductor layer and having a two-layer structure in which the first insulating layer including a silicon nitride layer and the second insulating layer including a silicon oxide layer are laminated.
(4) The light receiving element according to any one of (1) to (3), in which the semiconductor layer has a film thickness equal to or more than 10 nm and equal to or less than 30 nm.
(5) The light receiving element according to any one of (1) to (4), further including: a transparent electrode layer arranged between the semiconductor layer and the first insulating layer.
(6) The light receiving element according to (5), further including: a third insulating layer arranged between the transparent electrode layer and the first insulating layer, containing silicon oxide, and having a film thickness equal to or less than 10 nm.
(7) The light receiving element according to any one of (1) to (6), further including: a fourth insulating layer arranged between the semiconductor layer and the first insulating layer, containing silicon oxide, and having a film thickness equal to or less than 10 nm.
(8) The light receiving element according to any one of (1) to (7), further including: a fifth insulating layer arranged between the first insulating layer and the second insulating layer, containing at least one of aluminum oxide, magnesium oxide, or titanium oxide, and having a film thickness equal to or less than 10 nm.
(9) The light receiving element according to any one of (1) to (8), further including: a sixth insulating layer arranged on the light incident surface side than the second insulating layer, containing at least one of silicon nitride, aluminum oxide, magnesium oxide, or titanium oxide, and having a film thickness equal to or less than 10 nm.
(10) The light receiving element according to any one of (1) to (9), in which the first insulating layer has a film thickness equal to or more than 20 nm and equal to or less than 180 nm.
(11) The light receiving element according to any one of (1) to (10), in which the second insulating layer has a film thickness equal to or more than 20 nm and equal to or less than 180 nm.
(12) The light receiving element according to any one of (1) to (11), in which the photoelectric conversion layer contains InGaAs.
(13) The light receiving element according to any one of (1) to (12), in which the photoelectric conversion layer has a layer structure in which a first layer containing InGaAs and a second layer containing GaAsSb are alternately laminated.
(14) The light receiving element according to any one of (1) to (11), in which the photoelectric conversion layer has a distorted InGaAs structure containing InₓGa₍₁₋ₓ₎As (x is equal to or more than 0.53).
(15) The light receiving element according to any one of (1) to (11), in which the photoelectric conversion layer contains the organic material of which a refractive index is equal to or more than three.
(16) The light receiving element according to any one of (1) to (15), in which the semiconductor layer contains InP, InGaAs, or InAlAs.
(17) An imaging element including:
a light receiving element; and
a filter configured to be arranged on a light incident surface side than the light receiving element and transmit light in a predetermined wavelength band, in which
the light receiving element includes
a photoelectric conversion layer that contains a compound semiconductor material or an organic material,
a semiconductor layer that is arranged on the light incident surface side than the photoelectric conversion layer, contains a compound semiconductor material, and has a film thickness thinner than the photoelectric conversion layer,
a first insulating layer that is arranged on the light incident surface side than the semiconductor layer, contains silicon nitride, and has a lower refractive index than the semiconductor layer, and
a second insulating layer that is arranged on the light incident surface side than the first insulating layer, contains silicon oxide, and has a lower refractive index than the first insulating layer.
(18) An imaging device in which a plurality of imaging elements each including a light receiving element, and
a filter that is arranged on a light incident surface side than the light receiving element and transmits light in a predetermined wavelength band is arranged in a one-dimensional or two-dimensional direction, in which
the light receiving element includes
a photoelectric conversion layer that contains a compound semiconductor material or an organic material,
a semiconductor layer that is arranged on the light incident surface side than the photoelectric conversion layer, contains a compound semiconductor material, and has a film thickness thinner than the photoelectric conversion layer,
a first insulating layer that is arranged on the light incident surface side than the semiconductor layer, contains silicon nitride, and has a lower refractive index than the semiconductor layer, and
a second insulating layer that is arranged on the light incident surface side than the first insulating layer, contains silicon oxide, and has a lower refractive index than the first insulating layer.

Aspects of the present disclosure are not limited to the above-described individual embodiments, but include various modifications that can be conceived by those skilled in the art, and the effects of the present disclosure are not limited to the above-described contents. That is, various additions, modifications, and partial deletions are possible without departing from the conceptual idea and spirit of the present disclosure derived from the matters defined in the claims and equivalents thereof.

### REFERENCE SIGNS LIST

30 Light receiving element
31 Imaging element
41, 41A, 41B Photoelectric conversion layer
42 to 44 Semiconductor layer
45 First insulating layer
46 Second insulating layer
49 Transparent electrode layer
50 Third insulating layer
51 Fourth insulating layer
52 Fifth insulating layer
53 Sixth insulating layer
100 Solid-state imaging device
L1 Visible light
L2 Infrared light
W0, Wo5 to Wo30, Wn5 to Wn30, Wn2o2 to Wn18o2, Wn2o10 to Wn18o10, Wn2o18 to Wn18o18, Wn2o2 to Wn2o18, Wn10o2 to Wn10o18, Wn18o2 to Wn18o18 Waveform

What is claimed is:

1. A light receiving element, comprising:
a photoelectric conversion layer containing a compound semiconductor material or an organic material;
a semiconductor layer arranged on a light incident surface side than the photoelectric conversion layer, containing a compound semiconductor material that prevents recombination of charges generated by photoelectric conversion by the photoelectric conversion layer, and having a film thickness thinner than the photoelectric conversion layer;
a first insulating layer arranged on the light incident surface side than the semiconductor layer, containing silicon nitride, and having a lower refractive index than the semiconductor layer; and
a second insulating layer arranged on the light incident surface side than the first insulating layer, containing silicon oxide, and having a lower refractive index than the first insulating layer.

2. The light receiving element according to claim 1, wherein a plurality of layers including the semiconductor layer, the first insulating layer, and the second insulating layer arranged on the light incident surface side from the photoelectric conversion layer have a smaller refractive index, as approaching a light incident surface.

3. The light receiving element according to claim 1, further comprising: an antireflection layer arranged on the light incident surface side than the semiconductor layer and having a two-layer structure in which the first insulating layer including a silicon nitride layer and the second insulating layer including a silicon oxide layer are laminated.

4. The light receiving element according to claim 1, wherein the semiconductor layer has a film thickness equal to or more than 10 nm and equal to or less than 30 nm.

5. The light receiving element according to claim 1, further comprising: a transparent electrode layer arranged between the semiconductor layer and the first insulating layer.

6. The light receiving element according to claim 5, further comprising: a third insulating layer arranged between the transparent electrode layer and the first insulating layer, containing silicon oxide, and having a film thickness equal to or less than 10 nm.

7. The light receiving element according to claim 1, further comprising: a fourth insulating layer arranged between the semiconductor layer and the first insulating layer, containing silicon oxide, and having a film thickness equal to or less than 10 nm.

8. The light receiving element according to claim 1, further comprising: a fifth insulating layer arranged between the first insulating layer and the second insulating layer, containing at least one of aluminum oxide, magnesium oxide, or titanium oxide, and having a film thickness equal to or less than 10 nm.

9. The light receiving element according to claim 1, further comprising: a sixth insulating layer arranged on the light incident surface side than the second insulating layer, containing at least one of silicon nitride, aluminum oxide, magnesium oxide, or titanium oxide, and having a film thickness equal to or less than 10 nm.

10. The light receiving element according to claim 1, wherein the first insulating layer has a film thickness equal to or more than 20 nm and equal to or less than 180 nm.

11. The light receiving element according to claim 1, wherein the second insulating layer has a film thickness equal to or more than 20 nm and equal to or less than 180 nm.

12. The light receiving element according to claim 1, wherein the photoelectric conversion layer contains InGaAs.

13. The light receiving element according to claim 1, wherein the photoelectric conversion layer has a layer structure in which a first layer containing InGaAs and a second layer containing GaAsSb are alternately laminated.

14. The light receiving element according to claim 1, wherein the photoelectric conversion layer has a distorted InGaAs structure containing InₓGa₍₁₋ₓ₎As (x is equal to or more than 0.53).

15. The light receiving element according to claim 1, wherein the photoelectric conversion layer contains the organic material of which a refractive index is equal to or more than three.

16. The light receiving element according to claim 1, wherein the semiconductor layer contains InP, InGaAs, or InAlAs.

17. An imaging element, comprising:
a light receiving element; and
a filter configured to be arranged on a light incident surface side than the light receiving element and transmit light in a predetermined wavelength band, wherein
the light receiving element includes
a photoelectric conversion layer that contains a compound semiconductor material or an organic material,
a semiconductor layer that is arranged on the light incident surface side than the photoelectric conversion layer, contains a compound semiconductor material, and has a film thickness thinner than the photoelectric conversion layer,
a first insulating layer that is arranged on the light incident surface side than the semiconductor layer, contains silicon nitride, and has a lower refractive index than the semiconductor layer, and
a second insulating layer that is arranged on the light incident surface side than the first insulating layer, contains silicon oxide, and has a lower refractive index than the first insulating layer.

18. An imaging device in which a plurality of imaging elements each including a light receiving element, and
a filter that is arranged on a light incident surface side than the light receiving element and transmits light in a predetermined wavelength band is arranged in a one-dimensional or two-dimensional direction, wherein
the light receiving element includes
a photoelectric conversion layer that contains a compound semiconductor material or an organic material,
a semiconductor layer that is arranged on the light incident surface side than the photoelectric conversion layer, contains a compound semiconductor material, and has a film thickness thinner than the photoelectric conversion layer,
a first insulating layer that is arranged on the light incident surface side than the semiconductor layer, contains silicon nitride, and has a lower refractive index than the semiconductor layer, and
a second insulating layer that is arranged on the light incident surface side than the first insulating layer, contains silicon oxide, and has a lower refractive index than the first insulating layer.
